(19) United States
(12) Patent Application Publication
(10) Pub. No.: US 2016/0197122 A1
(43) Pub. Date: Jul. 7, 2016

(54) ORGANIC PHOTOELECTRONIC DEVICES AND IMAGE SENSORS INCLUDING THE SAME

(71) Applicant: Samsung Electronics Co., Ltd., Suwon-si (KR)

(72) Inventors: Satoh RYUICHI, Numazu-si (JP); Kyu Sik KIM, Yongin-si (KR); Woo Young YANG, Hwaseong-si (KR); Yeon-Hee KIM, Seoul (KR); Yong-Young PARK, Gyeonggi-do (KR); Xianyu WENXU, Suwon-si (KR); Chang Seung LEE, Yongin-si (KR); Yong Wan JIN, Seoul (KR)

(21) Appl. No.: 14/794,532

(22) Filed: Jul. 8, 2015

(30) Foreign Application Priority Data
Jan. 5, 2015 (KR) 10-2015-0000725

(51) Int. Cl. H01L 27/30; H01L 51/44

(52) U.S. Cl. CPC H01L 27/307; H01L 51/442; H01L 51/448; H01L 2251/303

(57) ABSTRACT

Organic photoelectronic devices and image sensors including the organic photoelectronic devices, include a first light-transmitting electrode at a side where light enters, a second light-transmitting electrode opposite to the first light-transmitting electrode, an active layer between the first and second light-transmitting electrodes, and an ultraviolet (UV) ray blocking layer on the first light-transmitting electrode, wherein the ultraviolet (UV) ray blocking layer includes at least one metal oxide having a light transmittance of less than or equal to about 75% for light of less than or equal to about 380 nm.

### RELATED APPLICATIONS

This application claims priority to and the benefit of Korean Patent Application No. 10-2015-0000725 filed in the Korean Intellectual Property Office on Jan. 5, 2015, the entire contents of which are incorporated herein by reference.

### BACKGROUND

1. Field

Example embodiments relate to organic photoelectronic devices and image sensors including the same are disclosed.

2. Description of the Related Art

A photoelectronic device converts light into an electrical signal using photoelectric effects, it may include a photodiode, a phototransistor, and the like, and it may be applied to an image sensor, a solar cell, and the like.

An image sensor including a photodiode requires high resolution and thus a small pixel. At present, a silicon photodiode is widely used, but it has a problem of deteriorated sensitivity because it has a small absorption area due to small pixels. Accordingly, an organic material that is capable of replacing silicon has been researched.

The organic material has a high extinction coefficient and selectively absorbs light in a particular wavelength region depending on a molecular structure, and thus may simultaneously replace a photodiode and a color filter, and resultantly improve sensitivity and contribute to high integration.

The organic material-based photodiode has a problem that an organic material active layer therein easily causes a chemical reaction such as oxidation/reduction and the like with water, oxygen, and the like. Accordingly, research on introducing a protective layer for protection of the organic material-based photodiode from a contamination material such as water, oxygen, and the like is being undertaken.

On the other hand, when an image sensor and the like are manufactured by using an organic photoelectronic device, ultraviolet (UV) rays are radiated during a process of forming a microlens and the like disposed on the image sensor. Herein, the ultraviolet (UV) rays may damage the organic material active layer in the organic photoelectronic device and thus critically deteriorate characteristics of the image sensor such as increasing a dark current and the like.

### SUMMARY

Example embodiments relate to organic photoelectronic devices.

Example embodiments provide an organic photoelectronic device having an ultraviolet (UV) ray blocking layer for protecting an organic active layer from ultraviolet (UV) rays.

Example embodiments provide image sensors including the organic photoelectronic device.

According to example embodiments, an organic photoelectronic device includes a first light-transmitting electrode at a light incidence side, a second light-transmitting electrode opposite to the first light-transmitting electrode, an active layer between the first light-transmitting electrode and the second light-transmitting electrode, and an ultraviolet (UV) ray blocking layer on the first light-transmitting electrode, wherein the ultraviolet (UV) ray blocking layer includes at least one metal oxide having a light transmittance of less than or equal to about 75% for light of less than or equal to about 380 nm.

The at least one metal oxide may include at least one selected from the group consisting of molybdenum oxide, tungsten oxide, niobium oxide, zirconium oxide, titanium oxide, and combinations thereof.

The ultraviolet (UV) ray blocking layer may include a monolayer or multilayer. The monolayer or multilayer may include the at metal oxide.

The ultraviolet (UV) ray blocking layer may have a thickness of about 1 nm to about 50 nm.

The organic photoelectronic device may further include a thin film encapsulation layer on the ultraviolet (UV) ray blocking layer, or between the ultraviolet (UV) ray blocking layer and the first light-transmitting electrode.

The thin film encapsulation layer may include at least one inorganic oxide selected from AlₓO_{y} (0<x≦2 and 0y≦3), SiNₓ (0<x≦4), SiOₓ (0<x≦2), SiON, or a combination thereof.

The ultraviolet (UV) ray blocking layer may be formed by depositing the at least one metal oxide on the first light-transmitting electrode or on the thin film encapsulation layer by using thermal evaporation, chemical vapor deposition (CVD), sputtering, or atomic layer deposition (ALD).

The thin film encapsulation layer may be formed by depositing the at least one inorganic oxide on the first light-transmitting electrode or on the ultraviolet (UV) ray blocking film by using CVD, sputtering, or ALD.

The first light-transmitting electrode and the second light-transmitting electrode may each independently include at least one of indium tin oxide (ITO), indium zinc oxide (IZO), tin oxide (SnO), aluminum tin oxide (ATO), aluminum zinc oxide (AZO), and fluorine-doped tin oxide (FTO).

The first light-transmitting electrode may have a thickness of about 1 nm to about 100 nm.

The second light-transmitting electrode may have a thickness of about 1 nm to about 200 nm.

The active layer may selectively absorb light in a green wavelength region.

The active layer may include a p-type semiconductor compound having a maximum absorption peak in a wavelength region of about 500 nm to about 600 nm, and an n-type semiconductor compound having a maximum absorption peak in a wavelength region of about 500 nm to about 600 nm.

The active layer may selectively absorb light in a red wavelength region.

The active layer may selectively absorb light in a blue wavelength region.

According to example embodiments, an image sensor including the organic photoelectronic device is provided.

The image sensor may further include a microlens on the ultraviolet (UV) ray blocking film.

According to example embodiments, an image sensor includes a green pixel, a red pixel, and a blue pixel, wherein the green pixel includes the organic photoelectronic device and a green photo-sensing device electrically connected to the organic photoelectronic device, the red pixel includes a red filter and a red photo-sensing device, the blue pixel includes a blue filter and a blue photo-sensing device, the red photo-sensing device and the blue photo-sensing device are integrated in a semiconductor substrate positioned under the green pixel, and the red filter and the blue filter are respectively in each position corresponding to the red photo-sensing device and the blue photo-sensing device, between the semiconductor substrate and the green pixel.

The image sensor may further include a microlens on the green pixel.

According to example embodiments, an image sensor includes a green pixel, a red pixel, and a blue pixel, wherein the green pixel includes the organic photoelectronic device and a green photo-sensing device electrically connected to the organic photoelectronic device, the red pixel includes a red photo-sensing silicon photodiode, the blue pixel includes a blue photo-sensing silicon photodiode, and the red photo-sensing silicon photodiode is vertically under the blue photo-sensing silicon photodiode in a semiconductor substrate under the green pixel.

The image sensor may further include a microlens on the green pixel.

According to example embodiments, the likelihood of damage on an organic active layer in an organic photoelectronic device due to radiation of ultraviolet (UV) rays decreases during manufacture of the microlens, and also stability of the organic photoelectronic device against ultraviolet (UV) rays in the air improves during operation as time passes.

### BRIEF DESCRIPTION OF THE DRAWINGS

Example embodiments will be more clearly understood from the following detailed description taken in conjunction with the accompanying drawings. FIGS. 1-15 represent non-limiting, example embodiments as described herein.

FIG. 1 is a cross-sectional view showing an organic photoelectronic device according to example embodiments,

FIG. 2 is a cross-sectional view showing an organic photoelectronic device according to example embodiments,

FIG. 3 is a cross-sectional view showing an organic photoelectronic device according to example embodiments,

FIG. 4 is a cross-sectional view showing an organic CMOS image sensor according to example embodiments,

FIG. 5 is a cross-sectional view showing an organic CMOS image sensor according to example embodiments,

FIG. 6 is a cross-sectional view of an organic CMOS image sensor according to example embodiments,

FIG. 7 is a cross-sectional view showing an organic CMOS image sensor according to example embodiments,

FIG. 8 is a cross-sectional view showing an organic CMOS image sensor according to example embodiments,

FIG. 9 is a graph showing light transmittance depending on a thickness of a molybdenum oxide (MoOₓ) in a wavelength region of 200 nm to 900 nm,

FIG. 10 is a graph showing light transmittance depending on a thickness of a tungsten oxide (WOₓ) in a wavelength region of 200 nm to 900 nm,

FIG. 11 is a graph showing light transmittance depending on a thickness of a niobium oxide (Nbₓ) in a wavelength region of 200 nm to 900 nm,

FIG. 12 is a graph showing light transmittance depending on a thickness of a zirconium oxide (ZrOₓ) in a wavelength region of 200 nm to 900 nm,

FIG. 13 is a graph showing light transmittance depending on a thickness of a titanium oxide (TiOₓ) in a wavelength region of 200 nm to 900 nm,

FIG. 14 is a graph showing I-V characteristics depending on applied voltages before and after radiation of ultraviolet (UV) rays of the organic photoelectronic device including a molybdenum oxide (MoOₓ) ultraviolet (UV) ray blocking layer according to Example 1, and

FIG. 15 is a graph showing I-V characteristics depending on applied voltages before and after radiation of ultraviolet (UV) rays of the organic photoelectronic device without a molybdenum oxide (MoOₓ) ultraviolet (UV) ray blocking layer according to Comparative Example 1.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments.

As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments will hereinafter be described in detail, and may be easily performed by those who have common knowledge in the related art. However, this disclosure may be embodied in many different forms and is not construed as limited to the exemplary embodiments set forth herein.

As used herein, when a definition is not otherwise provided, the term “substituted” refers to one substituted with a substituent with a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C7 to C30 arylalkyl group, a C1 to C4 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C20 heterocycloalkyl group, and a combination thereof, instead of hydrogen of a compound.

As used herein, when specific definition is not otherwise provided, the term “hetero” refers to one including 1 to 3 heteroatoms selected from N, O, S, and P.

In order to more specifically describe example embodiments, various features will be described in detail with reference to the attached drawings. However, example embodiments described are not limited thereto.

Example embodiments relate to organic photoelectronic devices and image sensors including the same are disclosed.

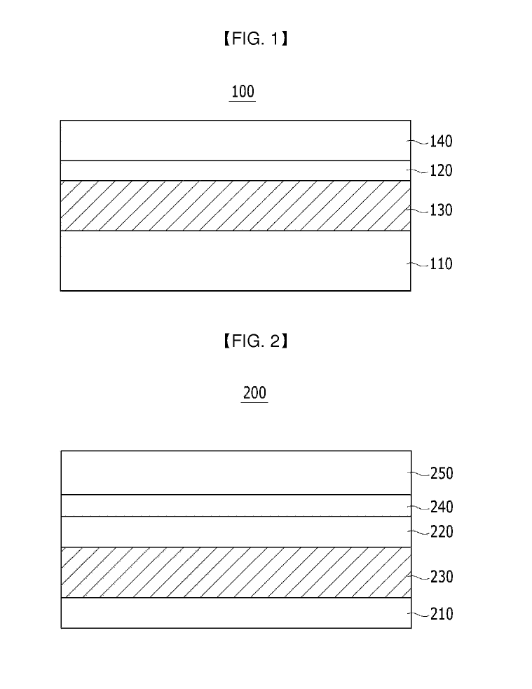

FIG. 1 is a cross-sectional view showing an organic photoelectronic device according to example embodiments.

Referring to FIG. 1, an organic photoelectronic device 100 includes a first light-transmitting electrode 120, a second light-transmitting electrode 110 opposite to the first light-transmitting electrode 120, a photoactive layer 130 interposed between the light-transmitting electrodes 110 and 120 and including an organic light-absorbing material, and an ultraviolet (UV) ray blocking layer 140 positioned on the first light-transmitting electrode 120.

In the present example embodiments, the first light-transmitting electrode 120 is a front side electrode positioned at a light incidence side, and the second light-transmitting electrode 110 is a back side electrode facing the first light-transmitting electrode 120. One of the first light-transmitting electrode 120 and the second light-transmitting electrode 110 is an anode, and the other is a cathode.

The ultraviolet (UV) ray blocking layer 140 is positioned on the first light-transmitting electrode 120 positioned at a light incidence side, and thus protects the photoactive layer 130 positioned therebeneath from the incident light, particularly ultraviolet (UV) rays. The ultraviolet (UV) rays blocking layer 140 may protect the photoactive layer 130 positioned therebeneath from the ultraviolet (UV) rays radiated during manufacture of microlens in a process of manufacturing an image sensor and the like, in an open process of an electrode pad and/or the like, as well as radiated in the air. In other words, the ultraviolet (UV) ray blocking layer 140 may protect the photoactive layer 130 from the radiation of ultraviolet (UV) rays during the manufacture or when used as a product.

In example embodiments, the ultraviolet (UV) ray blocking layer 140 may be a layer including a metal oxide having a light transmittance of less than or equal to about 75% for ultraviolet (UV) rays, for example light of less than or equal to about 380 nm.

The metal oxide may include molybdenum oxide, tungsten oxide, niobium oxide, zirconium oxide, titanium oxide, or a combination thereof.

The metal oxide transmits less than or equal to about 75% of light of less than or equal to about 380 nm, that is, ultraviolet (UV) rays, and thereby the organic photoelectronic device including the ultraviolet (UV) ray blocking layer 140 including the metal oxide may protect the photoactive layer 130 positioned under the ultraviolet (UV) ray blocking layer 140 from ultraviolet (UV) rays.

In example embodiments, the metal oxide may have transmittance of less than or equal to about 75%, for example less than or equal to about 70%, for example less than or equal to about 65%, for example less than or equal to about 55%, for example less than or equal to about 50%, for example less than or equal to about 45%, for example less than or equal to about 40%, for example less than or equal to about 35%, for example less than or equal to about 30%, for example less than or equal to about 25%, for example less than or equal to about 20%, for example less than or equal to about 15%, for example less than or equal to about 10%, or for example less than or equal to about 5%, for light of less than or equal to about 380 nm.

On the other hand, the metal oxide may have light transmittance of greater than about 55% for light in a wavelength region of greater than or equal to about 380 nm.

In example embodiments, the metal oxide may have light transmittance of greater than about 55%, for example greater than or equal to about 60%, for example greater than or equal to about 65%, for example greater than or equal to about 70%, for example greater than or equal to about 75%, for example greater than or equal to about 80%, for example greater than or equal to about 85%, or for example greater than or equal to about 90% in a wavelength region of greater than or equal to about 380 nm, for example light transmittance of greater than about 380 nm and less than or equal to about 780 nm.

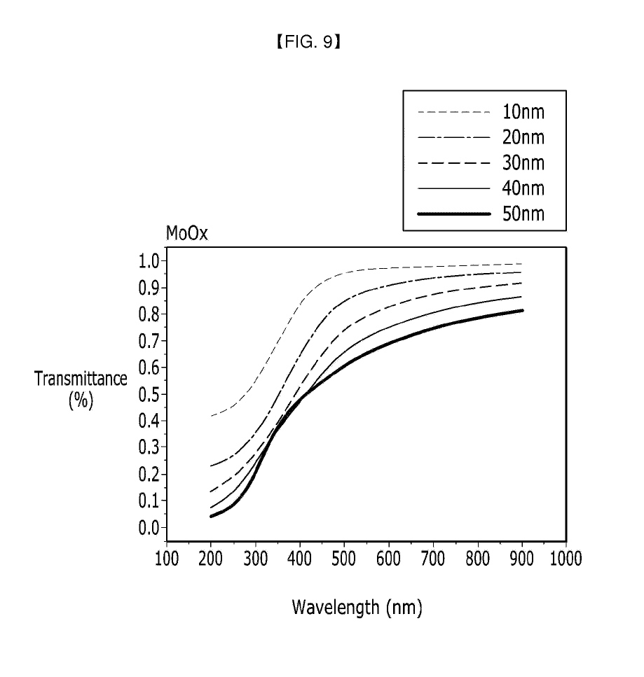

FIG. 9 is a graph showing light transmittance of a molybdenum oxide (MoOₓ) having a thickness of 10 nm to 50 nm in a wavelength region of 200 nm to 900 nm.

As shown in FIG. 9, light transmittance of a MoOₓ (wherein x<0≦3) is about 75% at a 380 nm wavelength when its thickness is about 20 nm, and its light transmittance increases in a wavelength region of greater than or equal to 380 nm, and is greater than or equal to about 90% in a 780 nm wavelength.

In this way, the MoOₓ effectively blocks ultraviolet (UV) rays of less than or equal to about 380 nm but efficiently delivers light in a wavelength region of greater than about 380 nm to the photoactive layer 130, and thus may be usefully used as a material for the ultraviolet (UV) ray blocking layer 140.

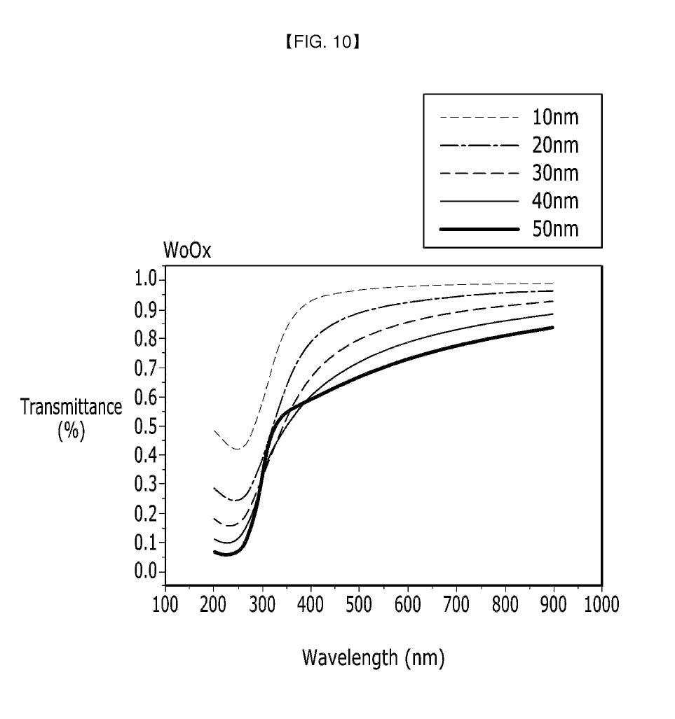

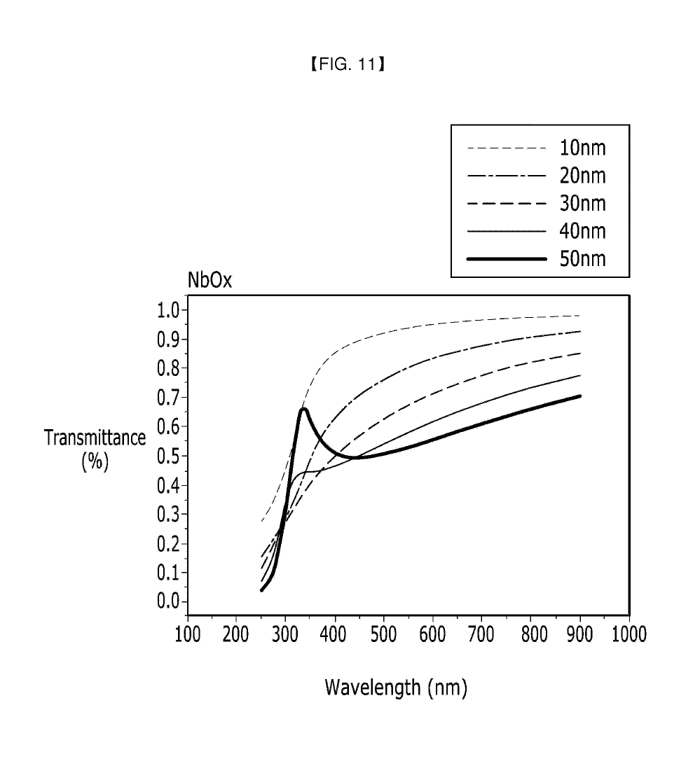

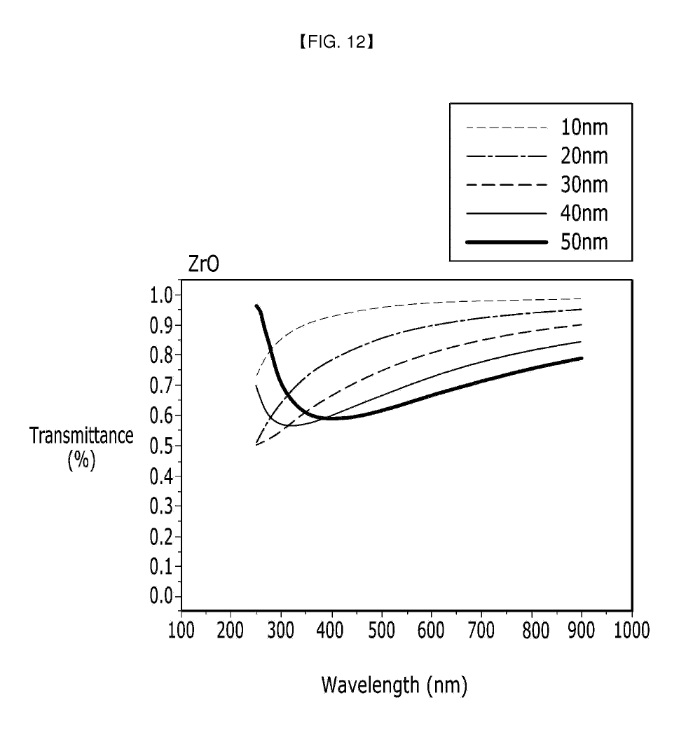

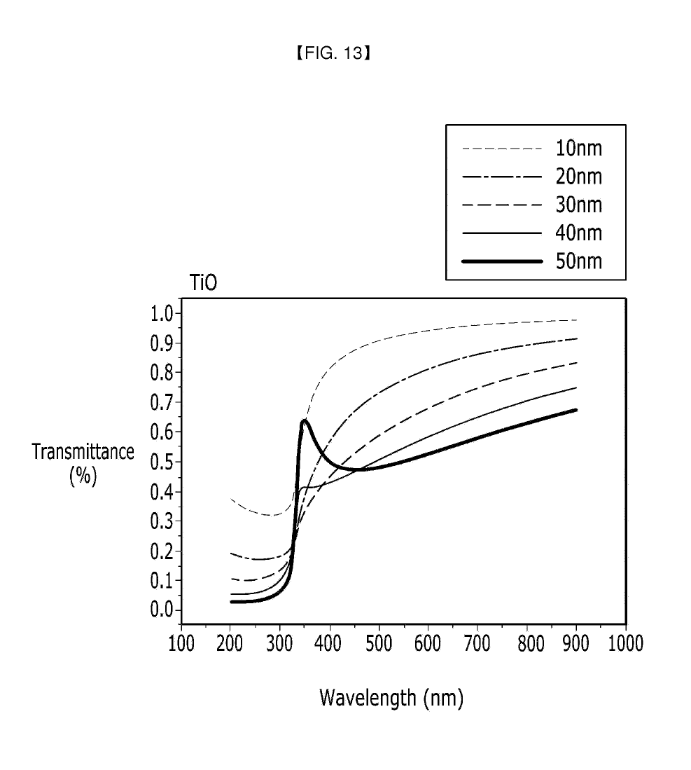

FIG. 10 is a graph showing light transmittance measured in a wavelength region of about 200 nm to about 900 nm by changing the thickness of tungsten oxide (WOₓ) (herein, 0<x≦2).

As shown in FIG. 10, the tungsten oxide shows sharply deteriorated light transmittance of less than or equal to about 75% in an ultraviolet (UV) region of less than or equal to about 380 nm when it has a thickness of about 20 nm, while the tungsten oxide shows high light transmittance of greater than about 80% in a visible ray region ranging from about 380 nm to about 780 nm. In other words, the tungsten oxide shows low transmittance of less than or equal to 75% in a ultraviolet (UV) region of less than or equal to about 380 nm and maintains high light transmittance in a visible ray region of greater than about 380 nm, and thus may be usefully used as an ultraviolet (UV) ray blocking layer for an organic photoelectronic device.

In addition to the above molybdenum oxide and tungsten oxide, niobium oxide, zirconium oxide, and titanium oxide show similar aspects, and thus these metals or a metal combination thereof may be usefully used as an ultraviolet (UV) ray blocking film material.

The ultraviolet (UV) ray blocking layer 140 may be formed by depositing the metal oxide on the first light-transmitting electrode by using, for example, thermal evaporation, chemical vapor deposition (CVD), sputtering, or atomic layer deposition (ALD).

The ultraviolet (UV) ray blocking layer 140 may have a stacking structure of two or more layers.

The stacking structure of two or more layers may include two or more layers each of which includes the same or different metal oxides of the above metal oxides, or a combination thereof.

The ultraviolet (UV) ray blocking layer 140 may have a total thickness of about 1 nm to about 50 nm.

Within the range, the ultraviolet (UV) ray blocking layer 140 may have a thickness of about 2 nm to about 30 nm. When the thickness is within the range, the ultraviolet (UV) ray blocking layer 140 may efficiently decrease damage to an active layer from ultraviolet (UV) rays without decreasing external quantum efficiency.

The first light-transmitting electrode 120 and the second light-transmitting electrode 110 may be any light-transmitting electrode for a photoelectronic device used for manufacture of an image sensor. For example, the light-transmitting electrode may be made of a transparent conductor such as indium tin oxide (ITO), indium zinc oxide (IZO), zinc oxide (ZnO), tin oxide (SnO), aluminum tin oxide (AITO), and fluorine doped tin oxide (FTO), or may be a metal thin layer having a thin thickness of several nanometers or several tens of nanometers or a metal thin layer having a thin thickness of several nanometers to several tens of nanometers doped with a metal oxide.

The photoactive layer 130 is a layer where p-type and n-type semiconductor materials form a pn flat junction or a bulk heterojunction, it may be formed as a single layer or multilayer, and plays a role of receiving light entering through the first light-transmitting electrode 120, producing an exciton, and then separating the exciton into a hole and an electron.

The produced excitons are separated into holes and electrons in the photoactive layer 130, and the separated holes are transferred to an anode and the separated electrons are transferred to a cathode, so as to flow a current in the organic photoelectronic device.

In example embodiments, the photoactive layer 130 includes p-type and n-type semiconductor materials which selectively absorb light in a green wavelength region, and photo-electrically convert it into a green wavelength.

The photoactive layer 130 may include a p-type semiconductor compound having a maximum absorption peak in a wavelength region of about 500 nm to about 600 nm, and an n-type semiconductor compound having a maximum absorption peak in a wavelength region of about 500 nm to about 600 nm.

The p-type semiconductor material and the n-type semiconductor material may respectively have a bandgap of about 1.5 eV to about 3.5 eV, for example about 2.0 eV to about 2.5 eV. The p-type semiconductor material and the n-type semiconductor material having a bandgap within the range may absorb light of a green wavelength region and show a maximum absorption peak, for example, in a wavelength region of about 500 nm to about 600 nm.

The p-type semiconductor material and the n-type semiconductor material may have a full width at half maximum (FWHM) ranging from about 50 nm to about 150 nm in a light absorbance curve. Herein, the FWHM is a width of a wavelength corresponding to half of a maximum absorbance point, and a smaller width at half maximum indicates selective absorbance of light in a narrow wavelength region and high selectivity of wavelength. Accordingly, the materials having a FWHM within the range may have high selectivity for a green wavelength region.

The p-type semiconductor material and the n-type semiconductor material may have a LUMO energy level difference of about 0.2 to about 0.7 eV, for example about 0.3 to about 0.5 eV. When the p-type semiconductor material and the n-type semiconductor material in the active layer 130 have a LUMO energy level difference within the range, external quantum efficiency (EQE) may be improved and effectively adjusted depending on a bias applied thereto.

The p-type semiconductor material may be, for example, a compound such as N,N-dimethyl-quinacridone (DMQA) and a derivative thereof, diindenoperylene, and dibenzo{[f,f′]-4,4′,7,7′-tetraphenyl}diindeno[1,2,3-cd:1′,2′,3′-1 m]perylene, but is not limited thereto.

The n-type semiconductor material may be, for example, a compound such as dicyanovinyl-terthiophene (DCV3T) and a derivative thereof, perylene diimide, phthalocyanine and a derivative thereof, sub-phthalocyanine and a derivative thereof, or boron dipyrromethene (BODIPY) and a derivative thereof, but is not limited thereto.

Herein, the p-type and n-type semiconductor materials are respectively illustrated as a case of absorbing light of a green wavelength region, but are not limited thereto, and may selectively absorb light of a blue wavelength region or light of a red wavelength region.

The photoactive layer 130 may be a single layer or a multilayer. The photoactive layer 130 may be, for example, an intrinsic layer (I layer), a p-type layer/I layer, an I layer/n-type layer, a p-type layer/I layer/n-type layer, a p-type layer/n-type layer, and the like.

The intrinsic layer (I layer) may include the p-type semiconductor compound and the n-type semiconductor compound in a thickness ratio of about 1:100 to about 100:1. The compounds may be included in a thickness ratio ranging from about 1:50 to about 50:1 within the range, and specifically, about 1:10 to about 10:1, and more specifically, about 1:1. When the p-type and n-type semiconductors have a composition ratio within the range, an exciton may be effectively produced, and a pn junction may be effectively formed.

The p-type layer may include the p-type semiconductor compound, and the n-type layer may include the n-type semiconductor compound.

The photoactive layer 130 may have a thickness of about 1 nm to about 500 nm. Within the range, the photoactive layer 130 may have a thickness of about 5 nm to about 300 nm. When the photoactive layer 130 has a thickness within the range, the active layer may effectively absorb light, effectively separate holes from electrons, and transport them, effectively improving photoelectric conversion efficiency.

Hereinafter, referring to FIG. 2, an organic photoelectronic device according to example embodiments is described.

FIG. 2 is a cross-sectional view of an organic photoelectronic device according to example embodiments.

Referring to FIG. 2, an organic photoelectronic device 200 includes a first light-transmitting electrode 220, a second light-transmitting electrode 210 facing the first light-transmitting electrode 220, a photoactive layer 230 interposed between the light-transmitting electrodes 210 and 220 and including an organic light-absorbing material, an ultraviolet (UV) ray blocking layer 240 positioned on the first light-transmitting electrode 220, and a thin film encapsulation layer 250 positioned on the ultraviolet (UV) ray blocking layer 240.

In the present example embodiments, the first light-transmitting electrode 220 is a front side electrode positioned at a light incidence side, and the second light-transmitting electrode 210 is a back side electrode facing the first light-transmitting electrode 220. One of the first light-transmitting electrode 220 and the second light-transmitting electrode 210 is an anode, and the other is a cathode.

The first light-transmitting electrode 220 and the second light-transmitting electrode 210 according to the present example embodiments have the same structure as the first light-transmitting electrode 120 and second light-transmitting electrode 110 that are explained in the example embodiments referring to FIG. 1, and thus details therefor are not provided.

The photoactive layer 230 is a layer where p-type and n-type semiconductor materials form a pn flat junction or a bulk heterojunction, it may be formed as a single layer or multilayer, and plays a role of receiving light entering through the first light-transmitting electrode 220, producing an exciton, and then separating the exciton into a hole and an electron.

In example embodiments, the photoactive layer 230 includes a p-type semiconductor material and an n-type semiconductor material that selectively absorb light in a green wavelength region, and photo-electrically converts it into a green wavelength.

The photoactive layer 230 may include a p-type semiconductor compound having a maximum absorption peak in a wavelength region of about 500 nm to about 600 nm, and an n-type semiconductor compound having a maximum absorption peak in a wavelength region of about 500 nm to about 600 nm.

The produced excitons are separated into holes and electrons in the photoactive layer 230, and the separated holes are transferred to the anode and the separated electrons are transferred to the cathode, so as to flow a current in the organic photoelectronic device.

Other details for the photoactive layer 230 are the same as the photoactive layer 130 in the example embodiments referring to FIG. 1, and are not provided herein.

The ultraviolet (UV) ray blocking layer 240 is positioned on the first light-transmitting electrode 220 positioned at a light incidence side, and protects the photoactive layer 230 positioned therebeneath from the incident light, particularly ultraviolet (UV) rays. The ultraviolet (UV) ray blocking layer 240 may protect the photoactive layer 230 positioned therebeneath from the incident light, for example, ultraviolet (UV) rays radiated from a process of manufacturing microlens, an open process of an electrode pad and/or the like during the manufacture of an image sensor and the like, as well as radiated in the air. In other words, the ultraviolet (UV) ray blocking layer 240 may protect the photoactive layer 230 from the ultraviolet (UV) rays radiated during the manufacturing process or as a product after the manufacturing process.

In example embodiments, the ultraviolet (UV) ray blocking layer 240 is a layer including a metal oxide having transmittance of less than or equal to about 75 for ultraviolet (UV) rays, for example light of less than or equal to about 380 nm.

The metal oxide may include molybdenum oxide, tungsten oxide, niobium oxide, zirconium oxide, titanium oxide, or a combination thereof.

The structure of the ultraviolet (UV) ray blocking layer 240 is the same as that explained referring to FIG. 1, and thus details therefor are not provided.

In the present example embodiments, the thin film encapsulation layer 250 is positioned on the ultraviolet (UV) ray blocking layer 240.

The thin film encapsulation layer 250 is a dense film protecting an organic photoelectronic device from external moisture, gases, or the like. The thin film encapsulation layer 250 may include an organic material, an inorganic material, or a composite material of the organic and inorganic materials, and actually, any material as long as it is transparent and thermally strong, effectively blocks permeation of external moisture or gases, generates no out-gas, and has no negative influence on the organic photoelectronic device therebeneath may be used.

For example, the thin film encapsulation layer 250 may be prepared by sputtering or depositing a transparent inorganic oxide with a CVD or ALD method on the ultraviolet (UV) ray blocking layer 240.

The transparent inorganic oxide for preparing the thin film encapsulation layer 250 may include, for example, an inorganic oxide selected from AlxOy (0<x≦2 and 0<y≦3), SiNx (0<x≦4), SiOx (0<x≦2), SiON, or a combination thereof.

The thin film encapsulation layer 250 may have a thickness of about 10 nm to about 500 nm. When the thin film encapsulation layer 250 has a thickness within the range, the organic photoelectronic device 200 may be effectively protected from external moisture and gases.

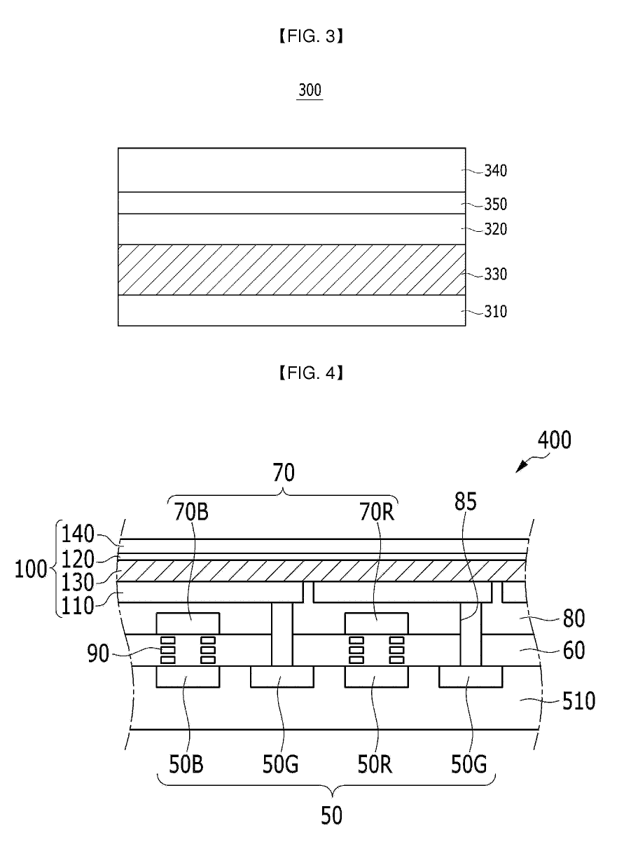

Hereinafter, an organic photoelectronic device according to example embodiments is described referring to FIG. 3.

FIG. 3 is a cross-sectional view showing an organic photoelectronic device according to example embodiments.

Referring to FIG. 3, an organic photoelectronic device 300 includes a first light-transmitting electrode 320, a second light-transmitting electrode 310 facing the first light-transmitting electrode 320, a photoactive layer 330 interposed between the light-transmitting electrodes 310 and 320 and including an organic light-absorbing material, a thin film encapsulation layer 350 positioned on the first light-transmitting electrode 320, and an ultraviolet (UV) ray blocking layer 340 positioned on the thin film encapsulation layer 350.

In the present example embodiments, the first light-transmitting electrode 320 is a front side electrode positioned at a light incidence side, and the second light-transmitting electrode 310 is a back side electrode facing the first light-transmitting electrode 320. One of the first light-transmitting electrode 320 and the second light-transmitting electrode 310 is an anode, and the other is a cathode.

The first light-transmitting electrode 320 and the second light-transmitting electrode 310 according to the present example embodiments has the same structure as the first light-transmitting electrode 120 and second light-transmitting electrode 110 that are explained in the example embodiments referring to FIG. 1, and thus details therefor are not provided.

The photoactive layer 330 is a layer where p-type and n-type semiconductor materials form a pn flat junction or a bulk heterojunction, it may be formed as a single layer or multilayer, and plays a role of receiving light entering through the first light-transmitting electrode 320, producing an exciton, and then separating the exciton into a hole and an electron.

The produced excitons are separated into holes and electrons in the photoactive layer 330, and the separated holes are transferred to the anode side and the separated electrons are transferred to a cathode, so as to flow a current in the organic photoelectronic device.

In example embodiments, the photoactive layer 330 includes a p-type semiconductor material and an n-type semiconductor material which selectively absorb light in a green wavelength region, and photo-electrically converts it into a green wavelength.

The photoactive layer 330 may include a p-type semiconductor compound having a maximum absorption peak in a wavelength region of about 500 nm to about 600 nm, and an n-type semiconductor compound having a maximum absorption peak in a wavelength region of about 500 nm to about 600 nm.

Other details for the photoactive layer 330 are the same as the photoactive layer 130 in the example embodiments referring to FIG. 1, and are not provided herein.

The present example embodiments are different from the example embodiments illustrated referring to FIG. 2 in that the thin film encapsulation layer 350 is positioned between the first light-transmitting electrode 320 and the ultraviolet (UV) ray blocking layer 340.

As described above, the thin film encapsulation layer 350 protects an organic photoelectronic device from external moisture or gases, and may be formed on the ultraviolet (UV) ray blocking film as shown in the example embodiments of FIG. 2 or between the ultraviolet (UV) ray blocking layer 340 and the first light-transmitting electrode 320 as shown in the present example embodiments.

The thin film encapsulation layer 350 may be formed of the same material as used in the example embodiments, but is different by being formed on the first light-transmitting electrode 320 before forming the ultraviolet (UV) ray blocking layer 340 in the manufacturing method. The ultraviolet (UV) ray blocking layer 340 may be formed on the thin film encapsulation layer 350.

For example, the thin film encapsulation layer 350 may be prepared by sputtering or depositing a transparent inorganic oxide with a CVD or ALD method on the first light-transmitting electrode 320.

Alternately, the thin film encapsulation layer 350 may be prepared by depositing a solution including an organic compound by a thermal evaporation method on the first light-transmitting electrode 320.

The thin film encapsulation layer 350 may have a thickness of about 10 nm to about 500 nm. When the thin film encapsulation layer 350 has a thickness within the range, the organic photoelectronic device 300 may be effectively protected from external moisture and gases. Other details for the thin film encapsulation layer 350 are the same as the thin film encapsulation layer 250 in the example embodiments referring to FIG. 2, and are not provided herein.

In the present example embodiments, the thin film encapsulation layer 350 is formed, and then the ultraviolet (UV) ray blocking layer 340 may be formed.

The ultraviolet (UV) ray blocking layer 340 is positioned on the first light-transmitting electrode 320 positioned at a light incidence side and on the thin film encapsulation layer 350 positioned thereon, and thus protects the photoactive layer 330 positioned therebeneath from the incident light, particularly ultraviolet (UV) rays. The ultraviolet (UV) ray blocking layer 340 may protect the photoactive layer 330 positioned therebeneath from the ultraviolet (UV) rays radiated in a process of manufacturing microlens, an open process of an electrode pad and/or during manufacture of an image sensor and the like, as well as radiated in the air. In other words, the ultraviolet (UV) ray blocking layer 340 may protect the photoactive layer 330 from the ultraviolet (UV) rays radiated during the manufacturing process or as a product therefrom.

In example embodiments, the ultraviolet (UV) ray blocking layer 340 may be a layer including a metal oxide having light transmittance of less than or equal to about 55% for ultraviolet (UV) rays, for example light of less than or equal to about 380 nm. The metal oxide may include molybdenum oxide, tungsten oxide, niobium oxide, zirconium oxide, titanium oxide, or a combination thereof.

The structure of the ultraviolet (UV) ray blocking layer 340 is the same as that explained referring to FIG. 1, and thus details therefor are not provided.

Although not shown in FIGS. 1 to 3, the organic photoelectronic devices 100, 200, and 300 may further include at least one charge auxiliary layer between the light-transmitting electrode and the photoactive layer. The charge auxiliary layer may facilitate the transfer of holes and electrons separated from the photoactive layer, so as to increase efficiency. For example, the charge auxiliary layer may be at least one of a hole injection layer (HIL) for facilitating hole injection, a hole transport layer (HTL) for facilitating hole transport, an electron blocking layer (EBL) for preventing electron transport, an electron injection layer (EIL) for facilitating electron injection, an electron transport layer (ETL) for facilitating electron transport, and a hole blocking layer (HBL) for preventing hole transport.

The hole transport layer (HTL) may include one selected from, for example, poly(3,4-ethylenedioxythiophene):poly(styrenesulfonate), (PEDOT:PSS), polyarylamine, poly(N-vinylcarbazole), polyaniline, polypyrrole, N,N,N′,N′-tetrakis(4-methoxyphenyl)-benzidine (TPD), 4-bis[N-(1-naphthyl)-N-phenyl-amino]biphenyl (α-NPD), m-MTDATA, 4,4′,4″-tris(N-carbazolyl)-triphenylamine (TCTA), tungsten oxide (WOₓ, 0<x≦3), molybdenum oxide (MoOₓ, 0<x≦3), vanadium oxide (V₂O₅), rhenium oxide, nickel oxide (NiOₓ, 1<x≦4), copper oxide, titanium oxide, sulfide molybdenum, and a combination thereof, but is not limited thereto.

The electron blocking layer (EBL) may include one selected from, for example, poly(3,4-ethylenedioxythiophene):poly(styrenesulfonate) (PEDOT:PSS), polyarylamine, poly(N-vinylcarbazole), polyaniline, polypyrrole, N,N,N′,N′-tetrakis(4-methoxyphenyl)-benzidine (TPD), 4-bis[N-(1-naphthyl)-N-phenyl-amino]biphenyl (α-NPD), m-MTDATA, 4,4′,4″-tris(N-carbazolyl)-triphenylamine (TCTA), and a combination thereof, but is not limited thereto.

The electron transport layer (ETL) may include one selected from, for example, 1,4,5,8-naphthalene-tetracarboxylic dianhydride (NTCDA), bathocuproine (BCP), LiF, Alq3, Gaq3, Inq3, Znq2, Zn(BTZ)2, BeBq₂, aluminum (Al), magnesium (Mg), molybdenum (Mo), aluminum oxide, magnesium oxide, molybdenum oxide, and a combination thereof, but is not limited thereto.

The hole blocking layer (HBL) may include one selected from, for example, 1,4,5,8-naphthalene-tetracarboxylic dianhydride (NTCDA), dicyanovinyl terthiophene (DCV3T), bathocuproine(BCP), LiF, Alq3, Gaq3, Inq3, Znq2, Zn(BTZ)₂, BeBq2, and a combination thereof, but is not limited thereto.

In the organic photoelectronic device, when light is incident from the one light-transmitting electrode and when the photoactive layer adsorbs light having a predetermined wavelength region, excitons may be produced from the inside. The excitons are separated into holes and electrons in the photoactive layer, and the separated holes are transported to an anode and the separated electrons are transported to the cathode, so as to flow a current in the organic photoelectronic device.

Hereinafter, an example of an image sensor including the organic photoelectronic device according to the example embodiments is described referring to drawings. As an example of an image sensor, an organic CMOS image sensor is described.

FIG. 4 is a cross-sectional view showing an organic CMOS image sensor according to example embodiments.

FIG. 4 exemplarily explains blue, green, and red pixels that are adjacent to one another, but it is not limited thereto. For instance, a cyan pixel, a magenta pixel and a yellow pixel may also be used if necessary.

Hereinafter, a constituent element including ‘B’ in the reference symbol refers to a constituent element included in the blue pixel, a constituent element including ‘G’ refers to a constituent element included in the green pixel, and a constituent element including ‘R’ in the reference symbol refers to a constituent element included in the red pixel.

Referring to FIG. 4, an organic CMOS image sensor 400 includes a semiconductor substrate 510 integrated with a photo-sensing device 50 and a transmission transistor (not shown), a lower insulation layer 60, a color filter 70, an upper insulation layer 80, and an organic photoelectronic device 100.

The semiconductor substrate 510 may be a silicon substrate, and is integrated with the photo-sensing device 50 and the transmission transistor (not shown). The photo-sensing device 50 may be a photodiode, or may store charges generated in the organic photoelectronic device 100. The photo-sensing device 50 and the transmission transistor may be integrated in each pixel, and as shown in the drawing, the photo-sensing device 50 includes a blue pixel photo-sensing device 50B, a green pixel photo-sensing device 500, and a red pixel photo-sensing device 50R. The photo-sensing device 50 senses light, and the information sensed by the photo-sensing device 50 is transferred by the transmission transistor.

Metal wires 90 and pads (not shown) are formed on the semiconductor substrate 510. In order to decrease signal delay, the metal wires 90 and pads may be made of a metal having low resistivity, for example, aluminum (Al), copper (Cu), silver (Ag), and alloys thereof, but is not limited thereto.

The lower insulation layer 60 is formed on the metal wires 90 and the pads. The lower insulation layer 60 may be made of an inorganic insulating material such as a silicon oxide and/or a silicon nitride, or a low dielectric constant (low K) material such as SiC, SiCOH, SiCO, and SiOF.

The lower insulation layer 60 has a trench exposing each photo-sensing device 50B, 50G, and 50R of each pixel. The trench may be filled with fillers.

The color filter 70 is formed on the lower insulation layer 60. The color filter 70 includes a blue filter 70B formed in the blue pixel and a red filter 70R filled in the red pixel. In the present example embodiments, a green filter is not included, but a green filter may be further included.

The upper insulation layer 80 is formed on the color filter 70. The upper insulation layer 80 eliminates a step caused by the color filters 70 and smoothes the surface. The upper insulation layer 80 and lower insulation layer 60 may include a contact hole (not shown) exposing a pad, and a through-hole 85 exposing the photo-sensing device 500 of a green pixel.

The organic photoelectronic device 100 is formed on the upper insulation layer 80. The organic photoelectronic device 100 includes the first light-transmitting electrode 120, the photoactive layer 130, the second light-transmitting electrode 110, and the ultraviolet (UV) ray blocking layer 140 as described above.

In example embodiments, the photoactive layer 130 includes p-type and n-type semiconductor materials which selectively absorb light in a green wavelength region, and photo-electrically converts it into a green wavelength.

Incident light first passes the ultraviolet (UV) ray blocking layer 140 which removes or decreases ultraviolet (UV) rays therefrom and the first light-transmitting electrode 120, and then reaches the photoactive layer 130, wherein light in a green wavelength region may be mainly absorbed and photoelectrically converted. Light in the rest of wavelength regions passes the second light-transmitting electrode 110 and may be sensed by the photo-sensing device 50.

The image sensor 400 may further include microlens on the ultraviolet (UV) ray blocking layer 140 (not shown). The microlens may be formed by a manufacturing process including an ultraviolet (UV) radiation process, and the image sensor 400 having the ultraviolet (UV) ray blocking layer 140 may protect the photoactive layer 130 in the organic photoelectronic device 100 from ultraviolet (UV) rays radiated in a process of forming the microlens.

A planarization layer (not shown) planarizing the top of the image sensor 400 may be further included before forming the microlens.

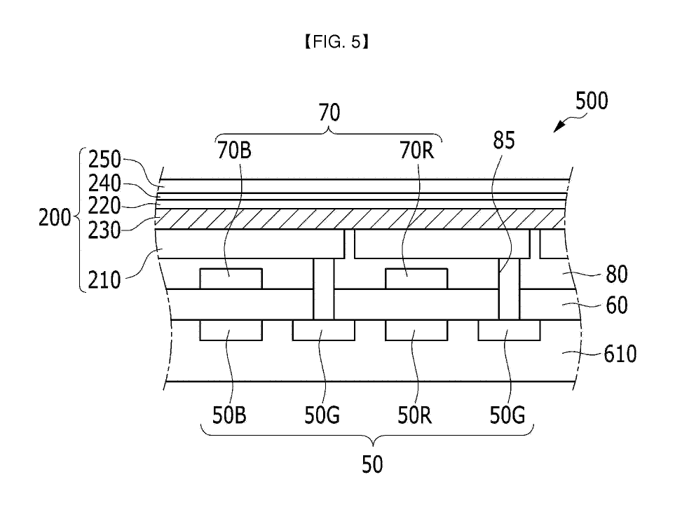

FIG. 5 is a cross-sectional view showing an organic CMOS image sensor according to example embodiments.

Referring to FIG. 5, an organic CMOS image sensor 500 according to the present example embodiments includes a semiconductor substrate 610 integrated with a photo-sensing device 50 and a transmission transistor (not shown), a lower insulation layer 60, a color filter 70, and an upper insulation layer 80, like the above example embodiments. However, the organic CMOS image sensor 500 includes the organic photoelectronic device 200 that further includes thin film encapsulation layer 250 on the ultraviolet (UV) ray blocking layer 240, instead of the organic photoelectronic device 100, unlike the above example embodiments.

The image sensor 500 may further include the ultraviolet (UV) ray blocking layer 240 and microlens (not shown) formed on the thin film encapsulation layer 250. The microlens may be formed by a manufacturing process including an ultraviolet (UV) radiation process, and the image sensor 500 having the ultraviolet (UV) ray blocking layer 240 may protect the photoactive layer 230 in the organic photoelectronic device 200 from the ultraviolet (UV) rays radiated during the process of forming the microlens.

Before forming the microlens, a planarization layer (not shown) planarizing the top of the image sensor 500 may be further included.

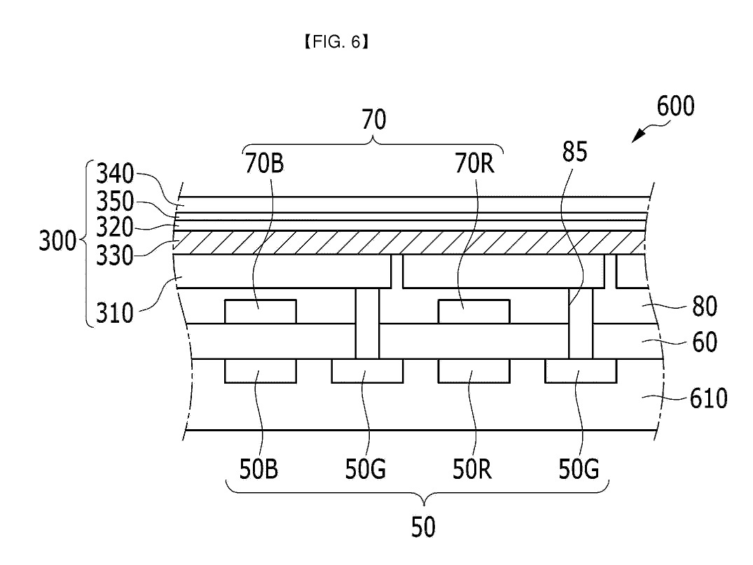

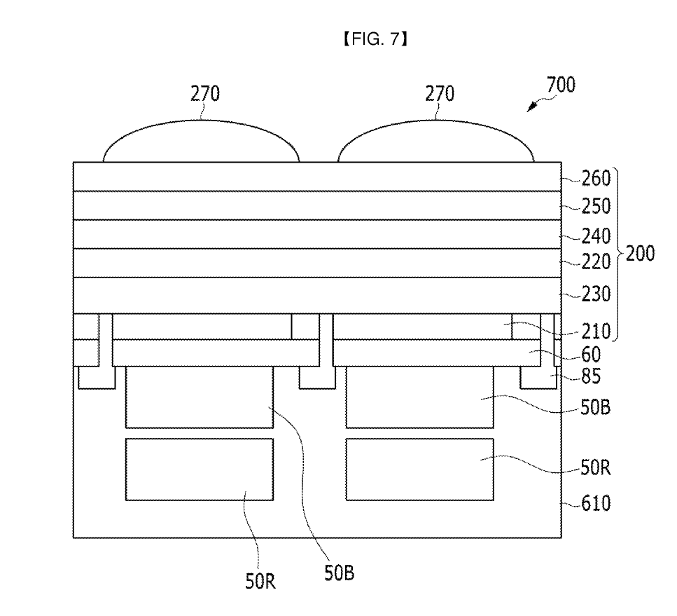

FIG. 6 is a cross-sectional view of an organic CMOS image sensor according to example embodiments.

Referring to FIG. 6, an organic CMOS image sensor 600 according to the present example embodiments includes a semiconductor substrate 610 integrated with a photo-sensing device 50 and a transmission transistor (not shown), a lower insulation layer 60, a color filter 70, and an upper insulation layer 80, like the above example embodiments. However, the organic CMOS image sensor 600 includes the organic photoelectronic device 300 that includes the thin film encapsulation layer 350 interposed between the ultraviolet (UV) ray blocking layer 340 and the first light-transmitting electrode 320, instead of the organic photoelectronic device 200, unlike the above example embodiments.

The image sensor 600 may further include microlens (not shown) on the ultraviolet (UV) ray blocking layer 340. The microlens may be formed by a manufacturing process including an ultraviolet (UV) radiation process, and the image sensor 600 having the ultraviolet (UV) ray blocking layer 340 may protect the photoactive layer 330 in the organic photoelectronic device 300 from the ultraviolet (UV) rays radiated during the process of forming the microlens.

Before forming the microlens, a planarization layer (not shown) planarizing the image sensor 700 may be further included.

FIG. 7 is a cross-sectional view showing an organic CMOS image sensor according to example embodiments.

Referring to FIG. 7, an organic CMOS image sensor 700 according to the present example embodiments includes a semiconductor substrate 610 integrated with a photo-sensing device 50 and a transmission transistor (not shown), a lower insulation layer 60, and the organic photoelectronic device 200 thereon. In other words, the organic CMOS image sensor 700 includes the organic photoelectronic device 200 including the thin film encapsulation layer 250 on the ultraviolet (UV) ray blocking layer 240.

However, blue and red pixels respectively include no color filter unlike the above example embodiments, but the red pixel is positioned beneath the blue pixel in the semiconductor substrate 610. In other words, the blue pixel consists of a silicon photodiode sensing blue light and the red pixel consists of a silicon photodiode sensing red light in the present example embodiments.

According to the present example embodiments, the image sensor 700 is similar to the image sensor 600 shown in FIG. 5 except that the blue and red pixels respectively consist of silicon photodiodes respectively sensing blue and red lights, and the red pixel is disposed beneath the blue pixel.

FIG. 7 shows that the planarization layer 260 is formed on the thin film encapsulation layer 250 of the organic photoelectronic device 200, and microlens 270 are formed on the planarization layer 260.

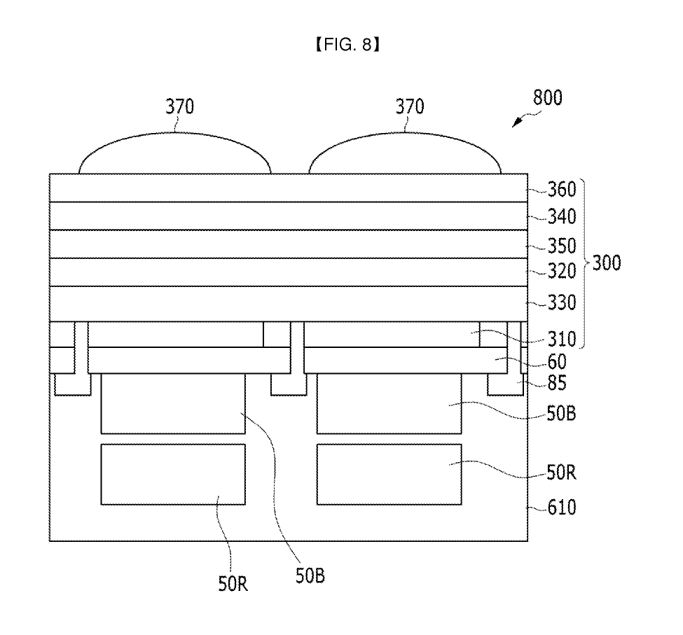

FIG. 8 is a cross-sectional view showing an organic CMOS image sensor according to example embodiments.

Referring to FIG. 8, an organic CMOS image sensor 800 is similar to that of FIG. 7, but includes the organic photoelectronic device 300 having the thin film encapsulation layer 350 between the ultraviolet (UV) ray blocking layer 340 and the first light-transmitting electrode 320. The other constituents of the organic CMOS image sensor 800 are the same as those of FIG. 7 and will not be illustrated in detail here.

Hereinafter, the present disclosure is illustrated in more detail with reference to examples. However, these examples are exemplary, and the present disclosure is not limited thereto.

### EXAMPLES

### Example 1

### Organic Photoelectronic Device Including Ultraviolet (UV) Ray Blocking Layer (MoOₓ)

An about 150 nm-thick lower electrode is formed by sputtering ITO on a glass substrate. Subsequently, on the lower electrode, a photoactive layer is formed by thermally depositing dicyanovinyl-terthiophene (DCV3T) to be 10 nm thick, dicyanovinyl-terthiophene (DCV3T):N,N′-dimethylquinacridone (DMQA) in a ratio of 1:1 to be 110 nm thick, HT211 to be 10 nm thick, and then HT211 and NPD9 in a ratio of 1:1 to be 15 nm thick. On the photoactive layer, a 6 nm-thick upper electrode is formed by sputtering ITO at a speed of 0.6 A/s for 100 seconds (DC 250 W, chamber pressure of 1 mTorr, Ar at 5 sccm, O₂ at 0.2 sccm), and on the upper electrode, a 10 nm-thick ultraviolet (UV) ray blocking layer is formed by thermally depositing molybdenum oxide (MoOₓ, 0<x≦3), manufacturing an organic photoelectronic device.

### Example 2

### Organic Photoelectronic Device Including Ultraviolet (UV) Ray Blocking Layer (WOₓ)

An organic photoelectronic device is manufactured according to the same method as Example 1, except for thermally depositing tungsten oxide (WOₓ, 0<x≦2) instead of the molybdenum oxide to form a 20 nm-thick ultraviolet (UV) ray blocking layer.

### Example 3

### Organic Photoelectronic Device Including Ultraviolet (UV) Ray Blocking Layer (NbOₓ)

An organic photoelectronic device is manufactured according to the same method as Example 1, except for thermally depositing niobium oxide (NbOₓ, 0<x≦2) instead of the molybdenum oxide to form a 10 nm-thick ultraviolet (UV) ray blocking layer.

### Example 4

### Organic Photoelectronic Device Including Ultraviolet (UV) Ray Blocking Layer (ZrOₓ)

An organic photoelectronic device is manufactured according to the same method as Example 1, except for depositing zirconium oxide (ZrOx, 0<x≦2) in an ALD method instead of the molybdenum oxide to form a 25 nm-thick ultraviolet (UV) ray blocking layer.

### Example 5

### Organic Photoelectronic Device Including Ultraviolet (UV) Ray Blocking Layer (TiOₓ)

An organic photoelectronic device is manufactured according to the same method as Example 1, except for EB-depositing titanium oxide (TiOₓ, 0<x≦2) instead of the molybdenum oxide to form a 10 nm-thick ultraviolet (UV) ray blocking layer.

### Comparative Example 1

### Organic Photoelectronic Device Including No Ultraviolet (UV) Ray Blocking Layer

An organic photoelectronic device is manufactured according to the same method as Example 1, except for depositing Al₂O₃ in an ALD method to form a 50 nm-thick thin film encapsulation layer instead of the ultraviolet (UV) ray blocking layer on the upper electrode when the lower electrode, the photoactive layer, and the upper electrode are sequentially deposited.

### Evaluation

Current-voltage characteristics of the organic photoelectronic devices are measured by using a semiconductor parameter analyzer (Keithley, 4200-SCS) and a dark box. Herein, dark currents (noise of a photodiode) of the organic photoelectronic devices are measured, that is, the dark currents are measured, because the sides of the organic photoelectronic devices to which a reverse bias is applied function as a light-receiving sensor.

Subsequently, external quantum efficiency (EQE) of the organic photoelectronic devices is measured by using an IPCE-measuring instrument (McScience, K3100). The external quantum efficiency (EQE) of the organic photoelectronic devices will not be illustrated in detail here but is the same as the EQE of a solar cell.

Particularly, the I-V (current-voltage) and EQE of the organic photoelectronic devices to examine their damage among many measurement items may be used to primarily screen the organic photoelectronic devices.

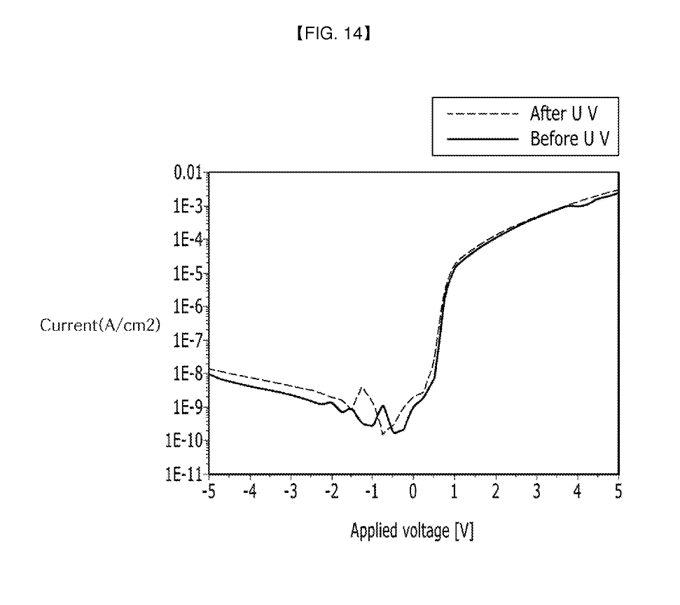

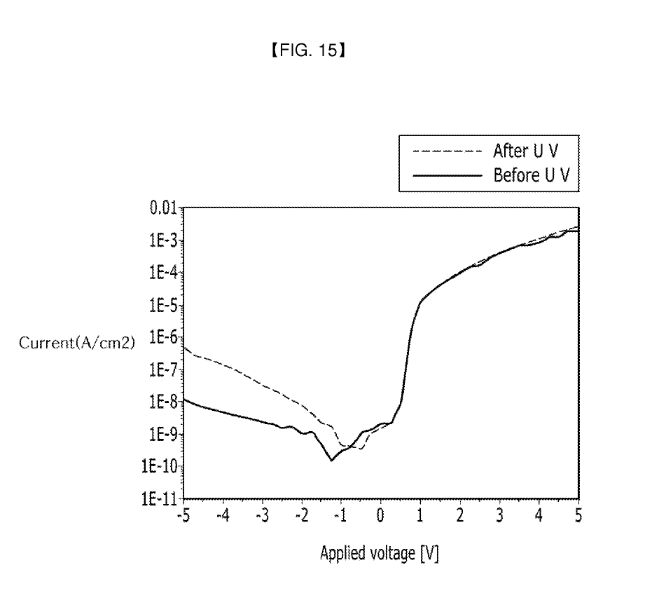

FIGS. 14 and 15 show the I-V characteristics, and whether the organic photoelectronic devices has damage or not is examined by checking if there is a change in current density of the reverse bias.

FIG. 14 is a graph showing current variation depending on applied voltages before and after radiation of ultraviolet (UV) rays of the organic photoelectronic device including a molybdenum oxide (MoOₓ) ultraviolet (UV) ray blocking layer according to Example 1

As shown in FIG. 14, an organic photoelectronic device including an ultraviolet (UV) ray blocking layer on a first light-transmitting electrode through which light enters has no large current change with respect to the applied voltage before and after radiating ultraviolet (UV) rays. In other words, the ultraviolet (UV) rays are effectively blocked by the ultraviolet (UV) ray blocking layer and there is no damage to the organic photoelectronic device.

FIG. 15 is a graph showing current variation depending on applied voltages before and after radiation of ultraviolet (UV) rays of the organic photoelectronic device without a molybdenum oxide (MoOₓ) ultraviolet (UV) ray blocking layer according to Comparative Example 1

As shown in FIG. 15, the organic photoelectronic device including no ultraviolet (UV) ray blocking layer according to Comparative Example 1 shows a large current change with respect to the applied voltage before and after radiating ultraviolet (UV) rays, which shows that the organic photoelectronic device is damaged by the ultraviolet (UV) rays.

While this disclosure has been described in connection with what is presently considered to be practical example embodiments, it is to be understood that the invention is not limited to the disclosed example embodiments, but, on the contrary, is intended to cover various modifications and equivalent arrangements included within the spirit and scope of the appended claims.

### DESCRIPTION OF SYMBOLS

100, 200, 300: organic photoelectronic device
110, 210, 310: second light-transmitting electrode
120, 220, 320: first light-transmitting electrode
130, 230, 330: photoactive layer
240, 340: ultraviolet (UV) ray blocking layer
250, 350: thin film encapsulation layer
400, 500, 600, 700, 800: organic CMOS image sensor
510, 610, 710, 810: semiconductor substrate
50: photo-sensing device
70: color filter
60, 80, 95: insulation layer

What is claimed is:

1. An organic photoelectronic device, comprising:
a first light-transmitting electrode at a light incidence side;
a second light-transmitting electrode opposite to the first light-transmitting electrode;
an active layer between the first light-transmitting electrode and the second light-transmitting electrode; and
an ultraviolet (UV) ray blocking layer on the first light-transmitting electrode, wherein the ultraviolet (UV) ray blocking layer includes at least one metal oxide having a light transmittance of less than or equal to about 75% for light of less than or equal to about 380 nm.

2. The organic photoelectronic device of claim 1, wherein the at least one metal oxide includes at least one selected from molybdenum oxide, tungsten oxide, niobium oxide, zirconium oxide, titanium oxide, and combinations thereof.

3. The organic photoelectronic device of claim 1, wherein the ultraviolet (UV) ray blocking layer includes a monolayer or multilayer, and the monolayer or multilayer includes the at least one metal oxide.

4. The organic photoelectronic device of claim 1, wherein the ultraviolet (UV) ray blocking layer has a thickness of about 1 nm to about 50 nm.

5. The organic photoelectronic device of claim 1, further comprising:
a thin film encapsulation layer on the ultraviolet (UV) ray blocking layer or between the ultraviolet (UV) ray blocking layer and the first light-transmitting electrode.

6. The organic photoelectronic device of claim 5, wherein the ultraviolet (UV) ray blocking layer is formed by depositing the at least one metal oxide in a method of thermal evaporation, sputtering, chemical vapor deposition (CVD) or atomic layer deposition (ALD) on the first light-transmitting electrode or the thin film encapsulation layer.

7. The organic photoelectronic device of claim 5, wherein the thin film encapsulation layer includes at least one inorganic oxide selected from AlₓO_{y} (herein, 0<x≦2 and 0<y≦3), SiNₓ (herein, x=0<x≦4), SiOₓ (herein x=0<x≦2), SiON, and combinations thereof.

8. The organic photoelectronic device of claim 7, wherein the thin film encapsulation layer is formed by depositing the at least one inorganic oxide on the first light-transmitting electrode or the ultraviolet (UV) ray blocking film in a method of thermal evaporation, sputtering, chemical vapor deposition (CVD) or atomic layer deposition (ALD).

9. The organic photoelectronic device of claim 1, wherein the first and second light-transmitting electrodes each independently include at least one selected from indium tin oxide (ITO), indium zinc oxide (IZO), tin oxide (SnO), aluminum tin oxide (ATO), aluminum zinc oxide (AZO), and fluorine-doped tin oxide (FTO).

10. The organic photoelectronic device of claim 1, wherein the first light-transmitting electrode has a thickness of about 1 nm to about 100 nm, and the second light-transmitting electrode has a thickness of about 1 nm to about 200 nm.

11. The organic photoelectronic device of claim 1, wherein the active layer selectively absorbs light in a green wavelength region.

12. The organic photoelectronic device of claim 11, wherein the active layer includes,
a p-type semiconductor compound having a maximum absorption peak in a wavelength region of about 500 nm to about 600 nm, and
an n-type semiconductor compound having a maximum absorption peak in a wavelength region of about 500 nm to about 600 nm.

13. The organic photoelectronic device of claim 1, wherein the active layer selectively absorbs light in a red wavelength region.

14. The organic photoelectronic device of claim 1, wherein the active layer selectively absorbs light in a blue wavelength region.

15. An image sensor, comprising:
the organic photoelectronic device according to claim 1.

16. The image sensor of claim 15, further comprising:
a microlens on the ultraviolet (UV) ray blocking film.

17. An image sensor, comprising:
a green pixel including the organic photoelectronic device according to claim and a green photo-sensing device electrically connected to the organic photoelectronic device;
a red pixel including a red filter and a red photo-sensing device; and
a blue pixel including a blue filter and a blue photo-sensing device,
the red and blue photo-sensing devices being integrated in a semiconductor substrate positioned beneath the green pixel, and
the red and blue filters being respectively in each position corresponding to the red photo-sensing device and the blue photo-sensing device between the semiconductor substrate and the green pixel.

18. The image sensor of claim 17, further comprising:
a microlens on the green pixel.

19. An image sensor, comprising:
a green pixel including the organic photoelectronic device of claim 11 and a green photo-sensing device electrically connected to the organic photoelectronic device;
a red pixel including a red photo-sensing silicon photodiode; and
a blue pixel including a blue photo-sensing silicon photodiode,
the red photo-sensing silicon photodiode being vertically under the blue photo-sensing silicon photodiode in a semiconductor substrate beneath the green pixel.

20. The image sensor of claim 19, further comprising:
a microlens on the green pixel.
